(19) United States
(12) Patent Application Publication
(10) Pub. No.: US 2025/0393461 A1
(43) Pub. Date: Dec. 25, 2025

(54) ELECTROSTATIC CHUCK, LASER LIFT-OFF APPARATUS INCLUDING ELECTROSTATIC CHUCK, AND METHOD OF MANUFACTURING DISPLAY DEVICE

(71) Applicant: Samsung Display Co., LTD., Yongin-si (KR)

(72) Inventors: Seung-Wan KIM, Yongin-si (KR); SEUNGHWAN YU, Yongin-si (KR); Hee-Won YOON, Yongin-si (KR); KYUNG-YEOL JUNG, Yongin-si (KR); SHINHYUK CHOI, Yongin-si (KR)

(21) Appl. No.: 19/248,226

(22) Filed: Jun. 24, 2025

(30) Foreign Application Priority Data
Jun. 25, 2024 (KR) 10-2024-0083169
Sep. 30, 2024 (KR) 10-2024-0133301

(51) Int. Cl. H10K 71/20; H01L 21/683

(52) U.S. Cl. CPC H10K 71/221; H01L 21/6833

(57) ABSTRACT

An electrostatic chuck includes a frame including a pair of supports facing each other and spaced apart from each other; and a variable electrode disposed between the pair of supports and configured to move. A laser lift off apparatus includes a chamber; the electrostatic chuck disposed in the chamber; and a laser source disposed above/below the electrostatic chuck and for irradiating laser beam.

This application claims priority to Korean Patent Application No. 10-2024-0133301, filed on Sep. 30, 2024, and Korean Patent Application No. 10-2024-0083169, filed on Jun. 25, 2024, and all the benefits accruing therefrom under 35 U.S.C. § 119, the contents of which in their entirety are herein incorporated by reference.

### BACKGROUND

### 1. Field

The present disclosure relates to an electrostatic chuck, a laser lift off apparatus including an electrostatic chuck, and a method for manufacturing a display device.

### 2. Description of the Related Art

With the advancement of display technology, organic light-emitting diode (OLED) displays are widely used in various applications due to their merits such as high quality, high contrast ratio, flexibility, and light weight. In particular, they are very popular because they may omit the backlight due to their self-light emitting characteristic and low power consumption. However, the process for manufacturing the OLED displays is complex and involves multiple steps, and the technology to separate the organic layer from the substrate without damages requires high precision and efficiency.

Laser lift off (LLO) technology plays an important role in this OLED display manufacturing process. The LLO technology selectively separates the bond between the organic layer and the substrate using a laser beam, allowing the organic layer to be removed without damage. However, the existing LLO technology had problems such as damage to the organic layer or difficulty in precise separation due to fine alignment errors or movement of the substrate. Although various technological approaches have been attempted to solve these problems, research is still ongoing to find the optimal solution.

### SUMMARY

The present disclosure attempts to provide an electrostatic chuck having a transformable electrode structure and being applicable to display panels with various types of designs, and a laser lift off apparatus including the same. The present disclosure attempts to provide a method for manufacturing a display device using a laser lift off apparatus including an electrostatic chuck.

An embodiment of the present disclosure provides an electrostatic chuck including: a frame including a pair of supports facing each other and spaced apart from each other; and a variable electrode disposed between the pair of supports and configured to move.

The pair of supports may be spaced apart from each other in a first direction, and the variable electrode may include an electrode bar extending along the first direction.

The electrode bar may be configured to move along a second direction perpendicular to the first direction, and the second direction may be a direction in which the pair of supports extend.

The electrode bar may include a first electrode pattern and a second electrode pattern having different polarities, the first electrode pattern may include a first stem extending along the first direction and a plurality of first branches extending from the first stem along a second direction perpendicular to the first direction, the second electrode pattern may include a second stem extending from the second stem along the first direction and a plurality of second branches extending along the second direction, and the first branches and the second branches may be alternately disposed along the first direction between the first stem and the second stem.

The electrode bar may include a first electrode pattern and a second electrode pattern having different polarities, and the first electrode pattern and the second electrode pattern may extend along the first direction and may be alternately disposed in a second direction perpendicular to the first direction.

The variable electrode may define a dechuck hole vertically penetrating therethrough, and may further include a dechuck pin positioned to be actuated vertically in the dechuck hole.

The electrostatic chuck may further include a dechuck pin actuator disposed in the frame, and the dechuck pin actuator may be connected to the dechuck pin through a link mechanism.

The pair of supports may further include a rail extending in a direction in which the pair of supports extend, and the variable electrode may further include a guide block mounted on the rail and movable along the rail.

The variable electrode may further include an electrode bar of which an end is fixed to the guide block.

The guide block may include a transport block mounted on the rail, and an electrode fixing block fixed to the transport block and connected to an end portion of the electrode bar.

The support may further include a fixing member facing the rail with the guide block therebetween, and the fixing member may be configured to press the guide block against the rail.

The support may further include an electromagnetic spring actuator connected to the fixing member and configured to be actuated vertically to move the fixing member.

The fixing member may have a protrusion-recess portion positioned on a surface facing the guide block.

The guide block may have a bump protruding from a surface facing the fixing member.

The variable electrode may be provided in plurality, and the plurality of variable electrodes may be configured to separately move relative to each other between the pair of supports.

The pair of supports may be spaced apart from each other in the first direction, and the plurality of variable electrodes may include a plurality of electrode bars extending parallel to each other along the first direction.

The at least one pair of the variable electrodes among the plurality of variable electrodes may be spaced apart from each other to have a through-opening vertically penetrating therebetween.

The one pair of supports may be spaced apart from each other in the first direction, and the through-opening may have a slit shape extending along the first direction.

Another embodiment of the present disclosure provides a laser lift off apparatus including: a chamber, an electrostatic chuck disposed in the chamber, and a laser source disposed above or below the electrostatic chuck to irradiate a laser beam. The electrostatic chuck includes a frame including a pair of supports facing each other and spaced apart from each other, and a variable electrode configured to move and disposed between the spaced pair of supports.

The pair of supports may be spaced apart in the first direction, and the variable electrode may include an electrode bar extending along the first direction.

The variable electrode may define a dechuck hole vertically penetrating therethrough, and may further include a dechuck pin positioned to be actuated vertically in the dechuck hole.

The pair of supports may further include a rail extending in a direction in which the pair of supports extend, and the variable electrode may further include a guide block mounted on the rail and movable along the rail.

The variable electrode may be provided in plurality, and the plurality of variable electrodes may be configured to separately move relative to each other between the pair of supports.

Another embodiment of the present disclosure provides a method for manufacturing a display device including: providing an electrostatic chuck in which a through-opening having a predetermined pattern is formed by moving a plurality of variable electrodes between a pair of supports, where the pair of supports face each other and are spaced apart from each other; attaching a display panel substrate to the electrostatic chuck to fix the display panel substrate; and performing a laser process of removing at least a portion of components of the display panel substrate by irradiating a laser beam to the display panel substrate through the through-opening.

The plurality of variable electrodes may be configured to separately move relative to each other, and the through-opening may be formed between the plurality of variable electrodes.

The laser process may include forming a hole into the display panel substrate by irradiating the laser beam to an active area for displaying an image in the display panel substrate.

According to the embodiments, the electrostatic chuck has the transformable electrode structure so it may be commonly applicable to the display panels with various types of designs.

As the laser lift off apparatus including the electrostatic chuck is applied to the process for manufacturing the organic light-emitting diode (OLED) display, the demand to manufacture different electrostatic chucks for the respective display panels with various types of models may be removed.

Therefore, the electrostatic chuck producing cost may be reduced, and the distribution load caused by storing multiple electrostatic chucks may be reduced. In addition, the production loss caused by replacing the electrostatic chucks may be effectively reduced.

### BRIEF DESCRIPTION OF THE DRAWINGS

FIG. 1 shows a laser lift off apparatus including an electrostatic chuck according to an embodiment.

FIG. 2 shows a perspective view of an electrostatic chuck according to an embodiment.

FIG. 3 shows a bottom perspective view of an electrostatic chuck shown in FIG. 2.

FIG. 4 shows a bottom view of an electrostatic chuck shown in FIG. 2.

FIG. 5 shows a perspective view of an individual variable electrode of an electrostatic chuck shown in FIG. 2.

FIG. 6 shows a side view showing an enlarged portion with a frame removed from the electrostatic chuck shown in FIG. 2.

FIG. 7 shows a top plan view of an electrode pattern configured in an electrode bar of an individual variable electrode shown in FIG. 5.

FIG. 8 shows a top plan view of an electrode pattern configured in an electrode bar of an individual variable electrode according to another embodiment.

FIG. 9 shows a perspective view showing an enlarged portion with a frame removed from the electrostatic chuck shown in FIG. 2.

FIG. 10 shows a cross-sectional view with respect to line X-X′ of FIG. 2.

FIG. 11 shows a perspective view of modifying arrangement by adjusting a gap among a plurality of electrode bars configuring an electrostatic chuck according to an embodiment.

FIG. 12 shows a cross-sectional view with respect to line XII-XII′ of FIG. 11.

FIG. 13 shows a perspective view of modifying arrangement by adjusting a gap among a plurality of electrode bars configuring an electrostatic chuck according to another embodiment.

FIG. 14 shows a perspective view of modifying arrangement by adjusting a gap among a plurality of electrode bars configuring an electrostatic chuck according to still another embodiment.

FIG. 15 shows a layout view of an example configured by moving an electrode bar of an electrostatic chuck according to an embodiment.

FIG. 16 shows a layout view of another example configured by moving an electrode bar of an electrostatic chuck according to an embodiment.

FIG. 17 shows a plan view of a variable electrode configuring an electrostatic chuck according to another embodiment.

FIG. 18 shows a plan view of a variable electrode configuring an electrostatic chuck according to still another embodiment.

FIG. 19 shows a processing diagram on a method for manufacturing a display device according to an embodiment.

FIG. 20 shows a schematic view on a process for forming a hole in active area (HIAA) in a display panel using a laser lift off apparatus according to an embodiment.

FIG. 21 shows a schematic view on a process for forming an under panel camera (UPC) on a display panel using a laser lift off apparatus according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

Parts that are irrelevant to the description are omitted to clearly describe the present disclosure, and like reference numerals designate like elements throughout the specification. In the drawings, the thickness of layers, films, panels, regions, etc., are enlarged for clarity. The thicknesses of some layers and areas are exaggerated for ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means disposed on or below the object portion, and does not necessarily mean disposed “on” or “above” the upper side of the object portion based on a gravitational direction.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Unless explicitly described to the contrary, the word “comprise”, and variations such as “comprises” or “comprising”, will be understood to imply the inclusion of stated elements but not the exclusion of any other elements.

The phrase “in a plan view” means viewing a target portion from the top, and the phrase “in a cross-sectional view” means viewing a cross-section formed by perpendicularly cutting a target portion from the side.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

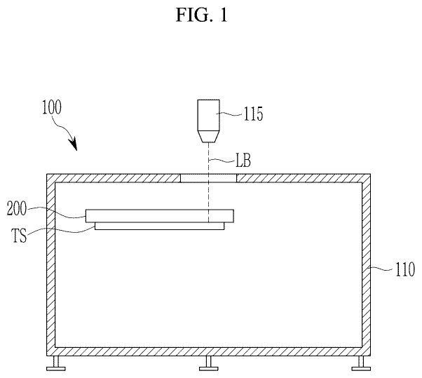

FIG. 1 shows a laser lift off apparatus including an electrostatic chuck according to an embodiment.

The laser lift off apparatus 100 provides a function for precisely removing a specific layer of the target substrate TS or patterning the same while a target substrate TS is fixed in the process for manufacturing displays. The laser lift off apparatus 100 may include an electrostatic chuck 200 disposed inside the vacuum chamber 110. The laser lift off apparatus 100 includes a laser source 115, and may, not shown in the drawing, further include a beam control device and a control system.

The vacuum chamber 110 is a closed space in which processes are performed, and it maintains an internal pressure at a low value to prevent impurities such as outside air or dusts from giving an influence on the display panel. By making a vacuum environment, problems such as oxidation may be prevented, and accuracy and reproducibility of the process may be increased.

The electrostatic chuck 200 is fixed into the vacuum chamber 110 and firmly affixes the target substrate TS. The electrostatic chuck 200 may be fixed inside the vacuum chamber 110 while being supported by a stage (not shown). The electrostatic chuck 200 may be an electrostatic derivative, and an electrostatic force may be induced as the voltage is applied. By fixing the target substrate TS immovably using the electrostatic force, precision of the operation may be enhanced by preventing minute movement or vibration that may occur during the process. By this, the position of the target substrate TS may be accurately maintained during the laser processing.

The target substrate TS represents an object in which holes are made using the laser lift off apparatus 100. The target substrate TS represents an object in which holes are made using the laser lift off apparatus 100. For example, the target substrate TS may be a display panel substrate including a glass substrate and a display panel layer formed on the glass substrate.

The laser source 115 generates a laser beam LB with a specific wavelength and selectively removes or separates a specific layer of the target substrate TS. A wavelength and an output power of the laser source 115 are adjusted according to requirements of the process, enabling highly precise patterning and removal operations. A high-power laser may be used as the laser source 115, for example, an excimer laser or an ultraviolet (UV) laser may be used to form fine structures or remove materials without damage.

The beam control device precisely adjusts position and intensity of the laser beam LB. Hence, the laser beam LB are accurately moved to the desired position, and they are adjusted with needed intensity so that they may give an influence to a specific portion of the display panel layer. The beam control device may precisely control the diameter, position, and moving speed of the laser beam LB to enable formation of various patterns or accurate removal of specific layers.

The control system may serve to manage and monitor the overall process. The control system real-time adjusts and optimizes a pressure of the vacuum chamber 110, a state of the electrostatic chuck, and operations of the laser source 115 and the beam control device.

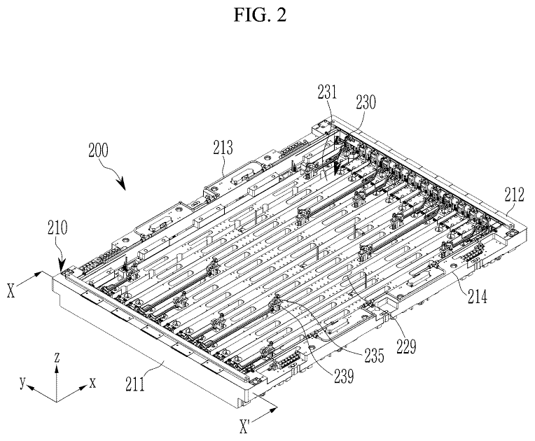

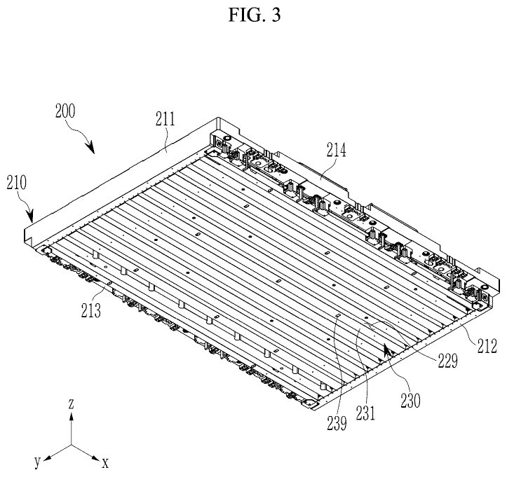

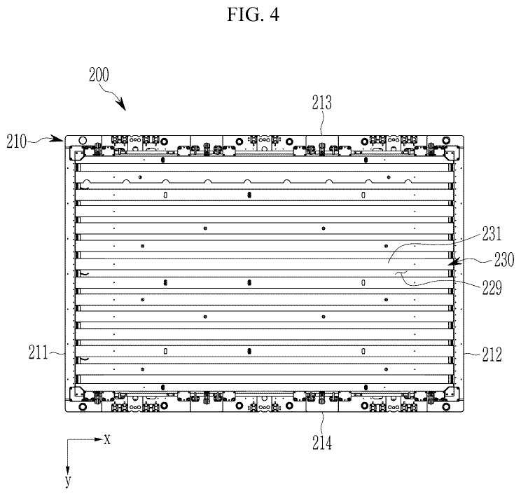

FIG. 2 shows a perspective view of an electrostatic chuck according to an embodiment, FIG. 3 shows a bottom perspective view of an electrostatic chuck shown in FIG. 2, and FIG. 4 shows a bottom view of an electrostatic chuck shown in FIG. 2.

Referring to FIG. 2 to FIG. 4, the electrostatic chuck 200 includes a frame 210 and a variable electrode 230 supported on the frame 210. The frame 210 includes at least one pair of supports 211 and 212 facing each other and spaced apart from each other, and the variable electrode 230 may be disposed between the one pair of supports 211 and 212.

The one pair of supports 211 and 212 may be spaced apart from each other in a first direction (x-axis direction in the drawing). The frame 210 may include one pair of connecting bars 213 and 214 for connecting the one pair of supports 211 and 212 to each other. The one pair of supports 211 and 212 may extend in a second direction (y-axis direction in the drawing) that is perpendicular to the first direction. The one pair of connecting bars 213 and 214 may extend in the first direction and may connect external end portions of the one pair of supports 211 and 212. Hence, the frame 210 of the electrostatic chuck 200 may have a shape having a substantially rectangular border. For example, extending lengths of the one pair of supports 211 and 212 may be shorter than extending lengths of the one pair of connecting bars 213 and 214, and the frame 210 of the electrostatic chuck 200 may substantially have a rectangular frame shape. However, the shape of the frame 210 may not be limited thereto.

The variable electrodes 230 may be provided in plurality, and the plurality of variable electrodes 230 may be configured to move while being separated from each other.

At least one pair of variable electrodes 230 from among the plurality of variable electrodes 230 may be spaced apart from each other and a gap between the at least one pair of variable electrodes 230 may be formed to be a through-opening 229 that penetrates from top to bottom in a third direction (z-axis direction in the drawing).

The plurality of variable electrodes 230 may include a plurality of electrode bars 231 extending along the first direction. The plurality of electrode bars 231 may extend in parallel to each other. The plurality of electrode bars 231 may move in the second direction (y-axis direction in the drawing) that is perpendicular to the first direction. The plurality of electrode bars 231 may be supported on the one pair of supports 211 and 212 and may be displaced in the direction (the second direction) in which the supports 211 and 212 extend. The through-opening 229 formed in the electrostatic chuck 200 may extend in the first direction in parallel to the electrode bar 231. Therefore, the through-opening 229 may have a narrow and long slit shape.

At least some of the variable electrodes 230 may define a dechuck hole 239 penetrating vertically (in z-axis direction), and a dechuck pin 235 may be disposed in the dechuck hole 239. The dechuck pin 235 may be driven in an up-down direction (z-axis direction in the drawing) in the dechuck hole 239 to push down and separate the target substrate TS attached to the electrostatic chuck 200.

Structures for mounting the electrostatic chuck 200 in the vacuum chamber 110 of the laser lift off apparatus 100 may be formed in the frame 210 of the electrostatic chuck 200. That is, the electrostatic chuck 200 may be fixed inside the laser lift off apparatus 100 by mounting the frame 210 inside the vacuum chamber 110. Mechanisms for guiding movements of the variable electrodes 230 or holding the variable electrodes 230 may be arranged on the frame 210 of the electrostatic chuck 200. Also, mechanisms for driving the dechuck pin 235 may be arranged on the frame 210 of the electrostatic chuck 200.

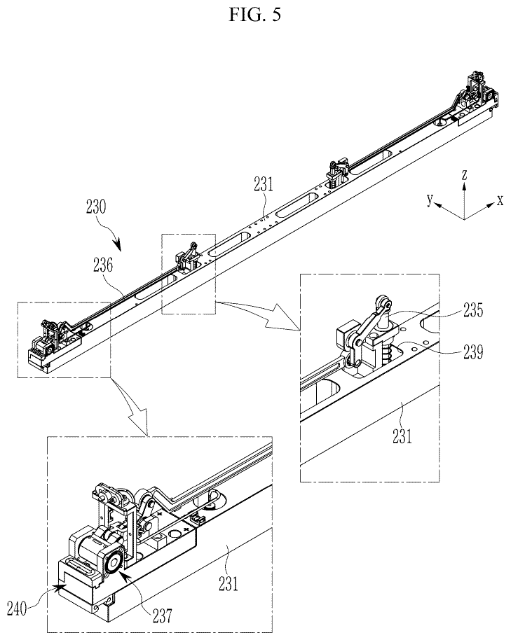

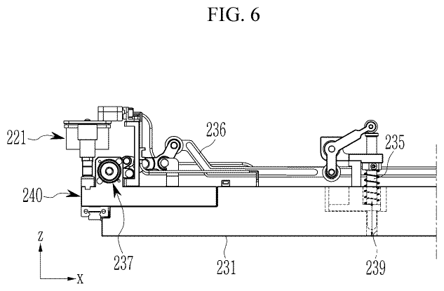

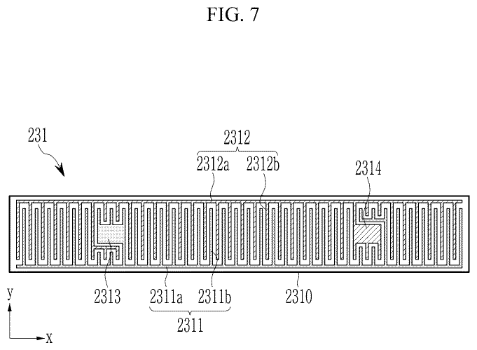

FIG. 5 shows a perspective view of an individual variable electrode of an electrostatic chuck shown in FIG. 2, FIG. 6 shows a side view showing an enlarged portion with a frame removed from the electrostatic chuck shown in FIG. 2, and FIG. 7 shows a top plan view of an electrode pattern configured in an electrode bar of an individual variable electrode shown in FIG. 5.

Referring to FIG. 5, the variable electrode 230 of the electrostatic chuck 200 includes an electrode bar 231 extending along the first direction (x-axis direction in the drawing). A guide block 240 is mounted on opposite end portions of the electrode bar 231 in the length direction (x-axis direction in the drawing). The guide block 240 may be integrally combined with the electrode bar 231 to configure the variable electrode 230. The guide block 240 may be engaged to the supports 211 and 212 (see FIG. 2) to fix the electrode bar 231 between the pair of supports 211 and 212. The guide block 240 may guide the movement of the electrode bar 231 in the elongation direction (y-axis direction in the drawing) of the supports 211 and 212 or may be fixed to specific points of the supports 211 and 212.

Referring to FIG. 6, the electrode bar 231 may extend longitudinally along the first direction (x-axis direction in the drawing) and may define a dechuck hole 239 penetrating in a top-to-bottom direction (z-axis direction in the drawing) through a portion thereof. The dechuck pin 235 may be housed in the dechuck hole 239, and may reciprocally move up and down in the dechuck hole 239 according to operation of the dechuck pin actuator 237. The dechuck pin actuator 237 may be located at the frame 210 (see FIG. 2), and the dechuck pin 235 may be connected to the dechuck pin actuator 237 through a link mechanism 236.

Referring to FIG. 7, each of the plurality of electrode bars 231 include a first electrode pattern 2311 and a second electrode pattern 2312 with different polarities. The first electrode pattern 2311 includes a first stem 2311a extending along the first direction (x-axis direction in the drawing) and a plurality of first branches 2311b extending along the second direction (y-axis direction in the drawing) from the first stem 2311a. The second electrode pattern 2312 includes a second stem 2312a extending along the first direction and a plurality of second branches 2312b extending along the second direction from the second stem 2312a.

The first stem 2311a and the second stem 2312a may extend in parallel to each other. The first branches 2311b may extend to the second stem 2312a from the first stem 2311a, and the second branches 2312b may extend to the first stem 2311a from the second stem 2312a. The first branches 2311b and the second branches 2312b may be alternately disposed in the first direction between the first stem 2311a and the second stem 2312a.

A first electrode connector 2313 may be disposed on one first branch 2311b of the first electrode pattern 2311, and a second electrode connector 2314 may be disposed on one second branch 2312b of the second electrode pattern 2312. The first electrode connector 2313 and the second electrode connector 2314 may have a greater area than the first branch 2311b or the second branch 2312b, respectively. The first electrode connector 2313 and the second electrode connector 2314 may be spaced apart from each other in the first direction.

For example, the first electrode pattern 2311 may be connected to a positive (+) electrode at the first electrode connector 2313, and the second electrode pattern 2312 may be connected to a negative (−) electrode at the second electrode connector 2314. A power voltage may be supplied to the electrode bars 231 through the first electrode connector 2313 and the second electrode connector 2314.

Each of the plurality of electrode bars 231 may include an electrode bar main body 2310 to surround the first electrode pattern 2311 and the second electrode pattern 2312. The electrode bar main body 2310 may be made of a ceramic material and may form external shapes of the respective electrode bars 231.

By supplying the power voltage to the first electrode pattern 2311 and the second electrode pattern 2312, attraction caused by the electrostatic force may be generated between the electrostatic chuck 200 and the substrate of the target substrate TS attached thereto. Hence, the target substrate TS may be electrostatically attached to the electrostatic chuck 200 and may be maintained.

Regarding the arrangement of the first electrode pattern 2311 and the second electrode pattern 2312, the number of electrodes, the lengths, and the connection forms (series or parallel) are modifiable depending on chucking specifications of the electrostatic chuck 200.

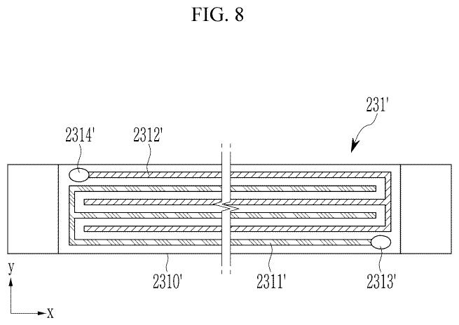

FIG. 8 shows a top plan view of an electrode pattern configured in an electrode bar of an individual variable electrode according to another embodiment.

Referring to FIG. 8, each of the plurality of electrode bars 231′ include a first electrode pattern 2311′ and a second electrode pattern 2312′ with different polarities. The first electrode pattern 2311′ and the second electrode pattern 2312′ may extend along the first direction (x-axis direction in the drawing) and may be alternately positioned in the second direction (y-axis direction in the drawing). For example, the first electrode pattern 2311′ may be connected to the positive (+) electrode at one end, and the second electrode pattern 2312′ may be connected to the negative (−) electrode at the other end. Connectors 2313′ and 2314′ for supplying power voltages to the electrode bars 231′ may be disposed on the first electrode pattern 2311′ and the second electrode pattern 2312′.

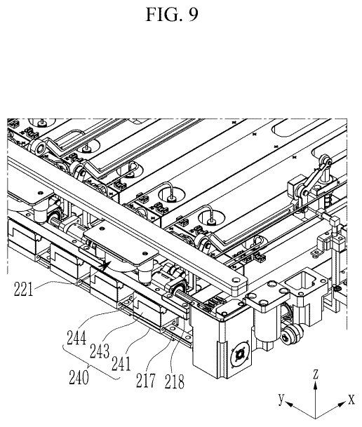

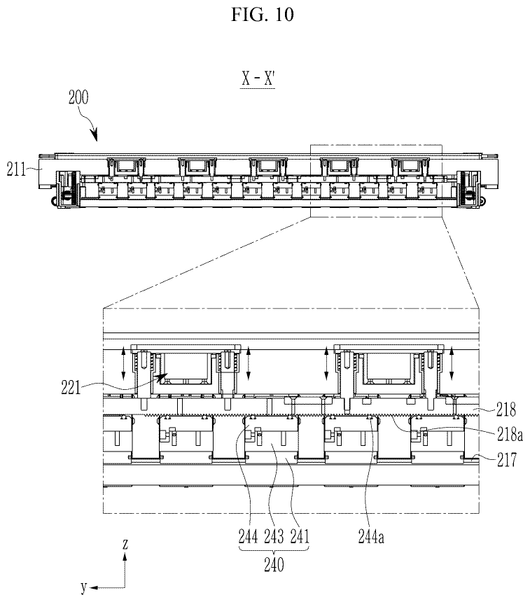

FIG. 9 shows a perspective view showing an enlarged portion with a frame removed from the electrostatic chuck shown in FIG. 2, and FIG. 10 shows a cross-sectional view with respect to line X-X′ of FIG. 2.

Referring to FIG. 9 and FIG. 10, each of the plurality of variable electrodes 230 may include a guide block 240 to support the electrode bars 231 on the supports 211 and 212 (see FIG. 2) of the frame 210 (see FIG. 2). The guide block 240 includes a transport block 241 mounted on a rail 217 and an electrode fixing block 243 fixed to the transport block 241. The electrode fixing block 243 may be connected to an end portion of the electrode bar 231. The supports 211 and 212 have the rail 217 extending in the second direction in them so that the transport block 241 may move along the rail 217 in the elongation direction (y-axis direction in the drawing) of the supports 211 and 212.

The supports 211 and 212 may include a fixing member 218 facing the rail 217 with the guide block 240 therebetween. The fixing member 218 may be configured to press the guide block 240 against the rail 217. That is, the fixing member 218 may be driven in a third direction (z-axis direction in the drawing) that is perpendicular to each of the first direction and the second direction, to press or release the guide block 240 against the rail 217. The guide block 240 may further include an upper block 244 fixed to the electrode fixing block 243. When the fixing member 218 is driven to press, the upper block 244 may contact the fixing member 218 and may provide a frictional force.

Referring to FIG. 10, the supports 211 and 212 (see FIG. 2) may include an electromagnetic spring actuator 221 for moving the fixing member 218. The electromagnetic spring actuator 221 may be connected to the fixing member 218 and may be driven as shown with an arrow direction in the drawing. That is, as the electromagnetic spring actuator 221 reciprocates in the third direction (or the z-axis direction in the drawing), it may move the fixing member 218 up and down.

The fixing member 218 may have a protrusion-recess portion 218a on a surface facing the guide block 240. The fixing member 218 with the protrusion-recess portion 218a may have a rack gear form. The upper block 244 of the guide block 240 may have a bump 244a slightly protruding on a surface facing the fixing member 218 and having elasticity. Therefore, when the fixing member 218 presses the guide block 240, the protrusion-recess portion 218a may press against the bump 244a. Hence, the fixing member 218 may more firmly affix the guide block 240, and the variable electrode 230 may not slide but may be fixed to a predetermined accurate position.

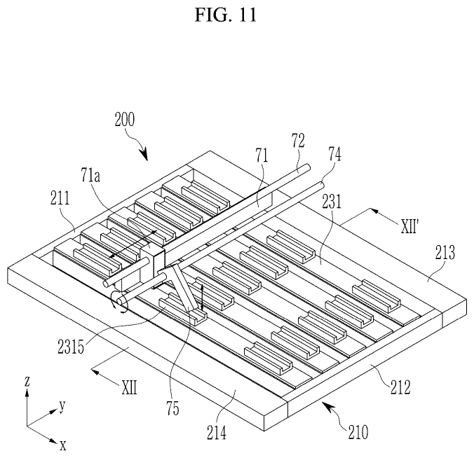

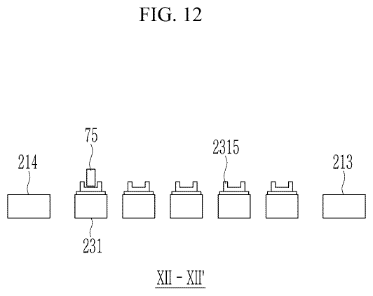

FIG. 11 shows a perspective view of modifying arrangement by adjusting a gap among a plurality of electrode bars configuring an electrostatic chuck according to an embodiment, and FIG. 12 shows a cross-sectional view with respect to line XII-XII′ of FIG. 11. Although the electrostatic chuck shown in FIG. 11 and FIG. 12 illustrates only five electrode bars with most components omitted for convenience of illustration, it is apparent that this may be similarly applied to the structure of the electrostatic chuck described with reference to FIGS. 1 to 10.

Referring to FIG. 11 and FIG. 12, a bar hold block 2315 may be attached to an upper end of each of the plurality of electrode bars 231 to adjust gaps among the plurality of electrode bars 231 of the electrostatic chuck 200. The bar hold block 2315 may have a groove extending along the first direction (x-axis direction in the drawing), and the bar hold pin 75 may be inserted into the groove to provide a driving force along the second direction (y-axis direction in the drawing). The bar hold blocks 2315 may be arranged in plurality, spaced apart from each other along the first direction at an upper portion of each electrode bar 231, for example, three bar hold blocks 2315 may be disposed at middle and opposite end portions. A bar hold pin 75 may be inserted into the bar hold block 2315 and may move the electrode bars 231.

The bar hold pin 75 may be made of an L-shaped structure, may move in the second direction, and may pivot with respect to a rotation axis in parallel to the second direction. To drive the bar hold pin 75, a linear motor (LM) guide 71, a ball screw 72, and a ball spline 74 may be provided. The LM guide 71, the ball screw 72, and the ball spline 74 may extend in the second direction at the upper portion of the electrostatic chuck 200. A transfer block 71a may be included in the LM guide 71, and the bar hold pin 75 may be received in the transfer block 71a. Therefore, when the transfer block 71a is driven along the LM guide 71, the bar hold pin 75 may reciprocate along the second direction.

On the other hand, a first end portion of the bar hold pin 75 may be fixed to the ball spline 74, and a second end portion thereof may be received in the groove of the bar hold block 2315. The ball spline 74 may rotate with respect to the rotation axis in parallel to the second direction. As the ball spline 74 rotates, the bar hold pin 75 of which the first end portion is fixed thereto pivots with respect to the rotation axis, and the second end portion may move up and down in the third direction (z-axis direction in the drawing). At this time, the bar hold pin 75 may be coupled to or decoupled from the bar hold block 2315.

Therefore, when a position of a designed electrode bar 231 is set, the electrode bar 231 may be moved to a desired position using the bar hold pin 75. By this, the electrostatic chuck 200 with the desired arrangement of electrode bars 231 may be easily provided.

FIG. 11 shows that one bar hold pin 75 is coupled to the bar hold block 2315 disposed on an intermediate portion of the electrode bar 231, and the bar hold pin 75 may be coupled to the bar hold block 2315 disposed on another portion that is not the intermediate portion of the electrode bar 231.

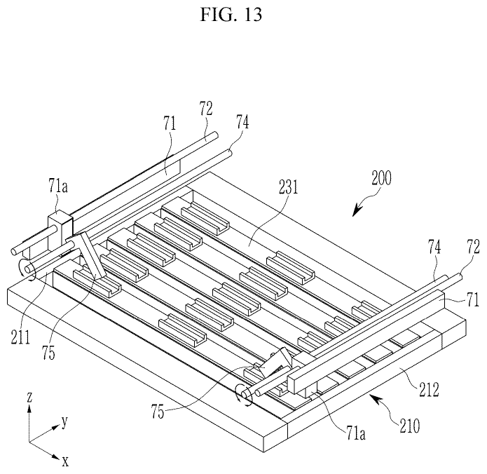

FIG. 13 shows a perspective view of modifying arrangement by adjusting a gap among a plurality of electrode bars configuring an electrostatic chuck according to another embodiment. Although the electrostatic chuck shown in FIG. 13 illustrates only five electrode bars with most components omitted for convenience of illustration, it may be similarly applied to the structure of the electrostatic chuck described with reference to FIGS. 1 to 10.

Referring to FIG. 13, one pair of bar hold pins 75 may be coupled to the bar hold block 2315 on opposite end portions of the electrode bar 231. To this end, the LM guide 71, the ball screw 72, and the ball spline 74 may be arranged on upper portion of the opposite end portions of the electrode bar 231. The one pair of bar hold pins 75 may be received in the one pair of transfer blocks 71a installed in the one pair of LM guide s71. The one pair of bar hold pins 75 disposed on opposite sides in the first direction may face each other with respect to the electrode bar 231.

As the ball spline 74 disposed on the upper portions of the opposite end portions of the electrode bar 231 rotates, the one pair of bar hold pins 75 pivots with respect to the rotation axis, and the end portion on the free end side may move up and down in the third direction (or the z-axis direction in the drawing). The one pair of bar hold pins 75 may be coupled to or decoupled from the one pair of bar hold blocks 2315 disposed on the opposite end portions of the electrode bar 231.

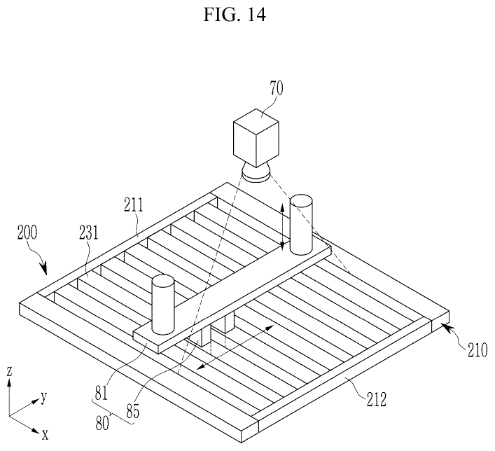

FIG. 14 shows a perspective view of modifying arrangement by adjusting a gap among a plurality of electrode bars configuring an electrostatic chuck according to still another embodiment.

Referring to FIG. 14, a vision camera 70 and robot pincers 80 may be provided to adjust the gaps among the plurality of electrode bars 231 of the electrostatic chuck 200.

The vision camera 70 may be positioned above the electrostatic chuck 200 to monitor arrangement of the plurality of electrode bars 231 while looking downward. For example, a reference may be set based on the frame 210 of the electrostatic chuck 200, and relative position coordinates of the plurality of electrode bars 231 may be calculated. Alternatively, the vision camera 70 may be disposed below the electrostatic chuck 200 to monitor while looking upward.

The robot pincers 80 may include at least one pair of fingers 85 combined to a base 81. A first end of the finger 85 may be fixed to the base 81 so that it may pivot or slide. A second end of the finger 85 may be configured as a free end and may be used to hold the electrode bar 231 of the electrostatic chuck 200. The robot pincers 80 may grasp the electrode bar 231 between the one pair of fingers 85 and may move the same to change the position of the electrode bar 231. The robot pincers 80 may lift in the third direction (z-axis direction in the drawing), and the finger 85 of the robot pincers 80 may reciprocate in the second direction (y-axis direction in the drawing).

Therefore, the desired position of the electrode bar 231 may be confirmed using the vision camera 70, and the electrode bar 231 may be moved to the desired position using the robot pincers 80. These operations may be performed for each of the plurality of electrode bars 231 to adjust gaps between the electrode bars 231. By this, the electrostatic chuck 200 with the desired arrangement of the electrode bars 231 may be easily provided.

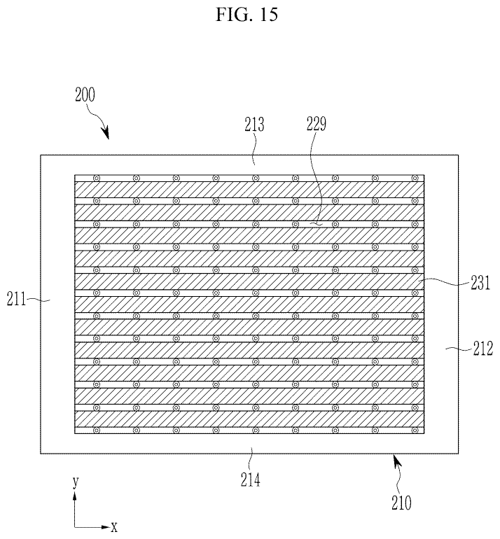

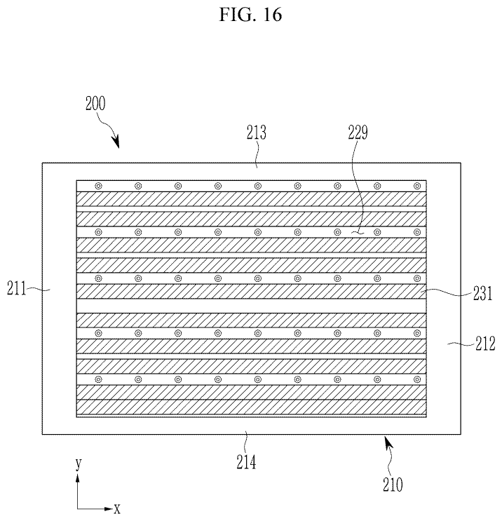

FIG. 15 shows a layout view of an example configured by moving an electrode bar of an electrostatic chuck according to an embodiment, and FIG. 16 shows a layout view of another example configured by moving an electrode bar of an electrostatic chuck according to an embodiment.

Referring to FIG. 15, the electrostatic chuck 200 includes eleven electrode bars 231. The eleven electrode bars 231 may be disposed between a pair of connecting bars 213 and 214 of the frame 210. Here, the eleven electrode bars 231 may be spaced apart from each other in the second direction (y-axis direction in the drawing). The electrode bars 231 disposed on the outermost part from among the eleven electrode bars 231 may be spaced apart from the connecting bars 213 and 214 with gaps therebetween. Therefore, the electrostatic chuck 200 shown in FIG. 16 may have through-openings 229 in twelve rows. The respective through-openings 229 in twelve rows may have a slit shape extending in the first direction (x-axis direction in the drawing).

Referring to FIG. 16, the eleven electrode bars 231 may be moved in the second direction (y-axis direction in the drawing) and twos or threes thereof neighboring each other may be adjacently arranged. For example, the three electrode bars 231 disposed in the middle may be disposed to contact each other, and the eight electrode bars 231 may be disposed near each other by twos. The electrode bars 231 disposed near the connecting bar 214 on one side may contact the connecting bar 214, and the electrode bars 231 disposed near the connecting bar 213 on another side may be spaced apart from the connecting bar 213 with a gap therebetween. Hence, the electrostatic chuck 200 shown in FIG. 15 may have through-openings 229 in five rows. The respective through-openings 229 in five rows may have a slit shape extending in the first direction (x-axis direction in the drawing).

According to the present embodiment, the electrostatic chuck 200 having different through-opening patterns may be provided by movably arranging the electrode bars 231.

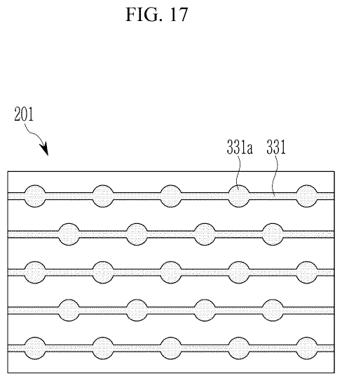

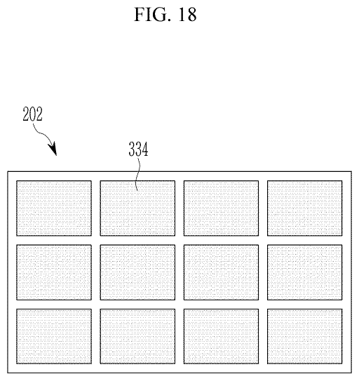

FIG. 17 shows a plan view of a variable electrode configuring an electrostatic chuck according to another embodiment, and FIG. 18 shows a plan view of a variable electrode configuring an electrostatic chuck according to the other embodiment.

The electrostatic chuck 200 described with reference to FIG. 1 to FIG. 16 has a structure including a plurality of bar-shaped electrodes. However, the electrode installed in the electrostatic chuck may not be limited to the bar shape. When the plurality of electrodes are individually driven and are spaced apart from each other to form a through-opening therebetween, the electrostatic chuck may include various shapes of electrodes, which also belongs to the range of the present disclosure.

For example, referring to FIG. 17, the individual variable electrode 331 installed in the electrostatic chuck 201 has a structure in which a plurality of protrusions 331a are added to the bar shape extending in the first direction (x-axis direction in the drawing). The plurality of protrusions 331a may be arranged in a staggered pattern between adjacent bar-shaped variable electrodes 331. That is, the protrusions 331a may be alternately arranged on the variable electrodes 331 in a bar shape in the second direction (y-axis direction in the drawing).

Regarding the electrostatic chuck 201 shown in FIG. 17, the configuration for moving the variable electrodes 331 may be formed in a like way of the structure of the electrostatic chuck 200 described with reference to FIG. 1 to FIG. 16.

For another example, referring to FIG. 18, the individual variable electrode 334 provided in the electrostatic chuck 202 may have a rectangular plate shape. The variable electrodes 334 in a rectangular plate shape may be arranged in a matrix pattern in the first direction and the second direction to have a tile structure. Configurations for movement of these rectangular plate-shaped variable electrode 334 may be provided on the frame of the electrostatic chuck 202.

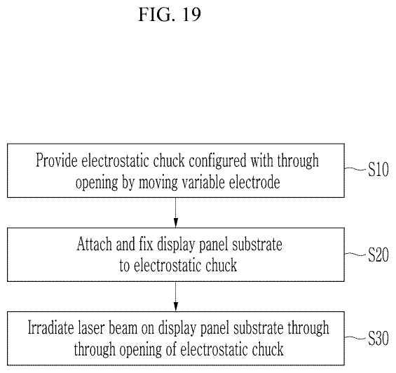

FIG. 19 shows a processing diagram on a method for manufacturing a display device according to an embodiment.

Referring to FIG. 19, the method for manufacturing a display device according to the present embodiment represents a method for manufacturing a display device using the electrostatic chucks 200, 201, and 202 and the laser lift off apparatus 100 described with reference to FIG. 1 to FIG. 18. The display panel substrate may be applied as the target substrate TS, and the display panel substrate may be a substrate for configuring the organic light-emitting diode (OLED) display.

First, an electrostatic chuck having through-openings of a predetermined pattern may be provided by moving the variable electrode (S10). The variable electrode of the electrostatic chuck may be disposed between one pair of supports facing each other and spaced apart from each other. The variable electrode may be moved between the one pair of supports.

The variable electrode may include a plurality of variable electrodes configured to be separated from each other and move. The plurality of variable electrodes may be relatively moved between the one pair of supports and may configure a through-opening with a predetermined pattern.

Next, a display panel substrate may be attached and fixed to the electrostatic chuck (S20). The display panel substrate may be fixed to one surface of the electrostatic chuck by an attraction caused by the electrostatic force of the electrostatic chuck.

A laser beam is irradiated to the display panel substrate through the through-opening of the electrostatic chuck (S30). At least some of the elements of the display panel substrate may be removed by a laser process. A portion of the processed display panel substrate may be an active area for displaying a screen. A hole may be formed by irradiating the laser beam to the active area.

When the laser process is completed, the dechuck pin included in the electrostatic chuck may be driven, and the display panel substrate may be separated from the electrostatic chuck. Subsequently, the display panel substrate may be moved to perform subsequent processes.

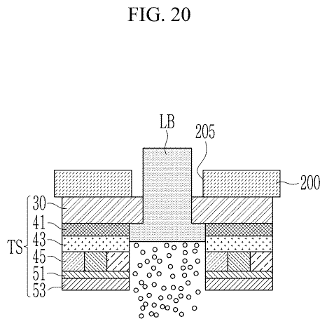

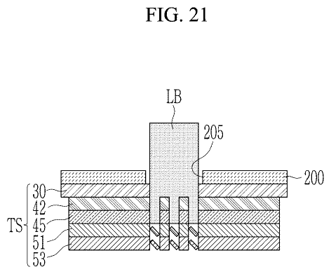

FIG. 20 shows a schematic view on a process for forming a hole in active area (HIAA) in a display panel using a laser lift off apparatus according to an embodiment, and FIG. 21 shows a schematic view on a process for forming an under panel camera (UPC) on a display panel using a laser lift off apparatus according to an embodiment.

The HIAA technique represents a process for forming fine holes in the active area of the display panel. The active area of the display panel drives the light-emitting element, emits light, and displays a screen. The HIAA forming process may be performed in a vacuum chamber of the laser lift off apparatus.

The UPC technique arranges a camera module on the lower end of the display panel and operates the camera if needed while it is covered by the screen in usual days. By this, the complete full screen without camera holes or notches may be realized on the entire surface of the display.

Referring to FIG. 20, to realize the HIAA process, a laser beam LB are irradiated to remove a portion of the target substrate TS while the target substrate TS is fastened to the electrostatic chuck 200. The target substrate TS may, for example, be a display panel substrate including a sacrificial layer 41, a common layer 43, a light-emitting layer 45, a cathode 51, and a capping layer 53 stacked on the glass substrate 30. The target substrate TS may be fixed to the electrostatic chuck 200 with the glass substrate 30 thereon, and the laser beam LB may be irradiated from a laser source disposed on the upper portion of the glass substrate 30. The laser beam LB may remove the sacrificial layer 41, the common layer 43, the light-emitting layer 45, the cathode 51, and the capping layer 53 of the selected region.

Referring to FIG. 21, for implementing the UPC technology, a portion of layers of the target substrate TS may be removed by irradiating a laser beam LB while the target substrate TS is held on the electrostatic chuck 200. The target substrate TS may, for example, be a display panel substrate including a bottom metal layer (BML) 42, a light-emitting layer 45, a cathode 51 and a capping layer 53 stacked on the glass substrate 30. The target substrate TS may be fixed to the electrostatic chuck 200 with the glass substrate 30 thereon, and the laser beam LB may be irradiated from the laser source disposed on the upper portion of the glass substrate 30. The laser beam LB may remove the cathode 51 and the capping layer 53 of the selected region.

To realize the HIAA or UPC technique, the laser beam LB are irradiated to the target substrate TS through the electrostatic chuck. Therefore, it is desirable to form the through-opening through which the laser beam LB pass in the electrostatic chuck.

The electrostatic chuck 200 may configure the through-opening 205 with different patterns (positions and sizes) depending on designs for respective models of the display panel generated by moving the plurality of variable electrodes 230.

Therefore, there is no need to manufacture or purchase the electrostatic chuck having a through-opening pattern optimized for the respective models of the display panel. Hence, production cost is reduced, and storage and management of the electrostatic chuck for the respective models are not needed, thereby reducing distribution loads. The time for replacing the changed electrostatic chuck may be effectively reduced and the production loss may be effectively reduced.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An electrostatic chuck comprising:
a frame including a pair of supports facing each other and spaced apart from each other; and
a variable electrode disposed between the pair of supports and configured to move.

2. The electrostatic chuck of claim 1, wherein
the pair of supports are spaced apart from each other in a first direction, and
the variable electrode includes an electrode bar extending along the first direction.

3. The electrostatic chuck of claim 2, wherein
the electrode bar is configured to move along a second direction perpendicular to the first direction, and
wherein the second direction is a direction in which the pair of supports extend.

4. The electrostatic chuck of claim 2, wherein
the electrode bar includes a first electrode pattern and a second electrode pattern having different polarities,
wherein the first electrode pattern includes a first stem extending along the first direction, and a plurality of first branches extending from the first stem along a second direction perpendicular to the first direction,
wherein the second electrode pattern includes a second stem extending along the first direction, and a plurality of second branches extending from the second stem along the second direction,
wherein the first branches and the second branches are alternately disposed along the first direction between the first stem and the second stem, and
wherein the second direction is a direction in which the pair of supports extend.

5. The electrostatic chuck of claim 2, wherein
the electrode bar includes a first electrode pattern and a second electrode pattern having different polarities,
wherein the first electrode pattern and the second electrode pattern extend along the first direction and are alternately disposed in a second direction perpendicular to the first direction, and
wherein the second direction is a direction in which the pair of supports extend.

6. The electrostatic chuck of claim 1, wherein
the variable electrode defines a dechuck hole vertically penetrating therethrough, and further includes a dechuck pin positioned to be actuated vertically in the dechuck hole.

7. The electrostatic chuck of claim 1, wherein
the pair of supports further include a rail extending in a direction in which the pair of supports extend, and the variable electrode further includes a guide block mounted on the rail and movable along the rail.

8. The electrostatic chuck of claim 7, wherein
the variable electrode further includes an electrode bar of which an end is fixed to the guide block.

9. The electrostatic chuck of claim 7, wherein
the support further includes a fixing member facing the rail with the guide block therebetween, and the fixing member is configured to press the guide block against the rail.

10. The electrostatic chuck of claim 9, wherein
the support further includes an electromagnetic spring actuator connected to the fixing member and configured to be actuated vertically to move the fixing member.

11. The electrostatic chuck of claim 1, wherein
the variable electrode is provided in plurality, and
the plurality of variable electrodes are configured to separately move relative to each other between the pair of supports.

12. The electrostatic chuck of claim 11, wherein
the pair of supports are spaced apart from each other in one direction, and
the plurality of variable electrodes include a plurality of electrode bars extending parallel to each other along the one direction.

13. A laser lift off apparatus comprising:
a chamber;
an electrostatic chuck disposed in the chamber; and
a laser source disposed above or below the electrostatic chuck to irradiate a laser beam,
wherein the electrostatic chuck includes
a frame including a pair of supports facing each other and spaced apart from each other, and a variable electrode configured to move and disposed between the spaced pair of supports.

14. The laser lift off apparatus of claim 13, wherein
the pair of supports are spaced apart in one direction, and
the variable electrode includes an electrode bar extending along the one direction.

15. The laser lift off apparatus of claim 13, wherein
the variable electrode defines a dechuck hole vertically penetrating therethrough, and further includes a dechuck pin positioned to be actuated vertically in the dechuck hole.

16. The laser lift off apparatus of claim 13, wherein
the pair of supports further include a rail extending in a direction in which the pair of supports extend, and the variable electrode may further include a guide block mounted on the rail and movable along the rail.

17. The laser lift off apparatus of claim 13, wherein
the variable electrode is provided in plurality, and
the plurality of variable electrodes are configured to separately move relative to each other between the pair of supports.

18. A method for manufacturing a display device comprising:
providing an electrostatic chuck in which a through-opening having a predetermined pattern is formed by moving a plurality of variable electrodes between a pair of supports, wherein the pair of supports face each other and are spaced apart from each other;
attaching a display panel substrate to the electrostatic chuck to fix the display panel substrate; and
performing a laser process of removing at least a portion of components of the display panel substrate by irradiating a laser beam to the display panel substrate through the through-opening.

19. The method of claim 18, wherein
the plurality of variable electrodes are configured to separately move relative to each other, and
the through-opening is formed between the plurality of variable electrodes.

20. The method of claim 18, wherein
the laser process includes forming a hole into the display panel substrate by irradiating the laser beam to an active area for displaying an image in the display panel substrate.
